(19) United States
(12) Patent Application Publication
(10) Pub. No.: US 2020/0033533 A1
(43) Pub. Date: Jan. 30, 2020

(54) ON-WAFER TESTING OF PHOTONIC CHIPS

(71) Applicant: Elenion Technologies, LLC, New York, NY (US)

(72) Inventors: Amit Khanna, Fremont, CA (US); Ari Jason Novack, New York, NY (US); Matthew Akio Streshinsky, New York, NY (US); Michael J. Hochberg, New York, NY (US)

(21) Appl. No.: 16/043,436

(22) Filed: Jul. 24, 2018

(51) Int. Cl. G02B 6/124; G02B 6/13; G02B 6/12; G01R 31/3185; G01M 11/00; G01R 31/308; H01L 21/66

(52) U.S. Cl. CPC G02B 6/124; G02B 6/13; G02B 6/12016; G02B 6/12019; G02B 2006/12176; G01R 31/318511; G01M 11/30; G01R 31/308; H01L 22/12; G02B 6/12004

(57) ABSTRACT

A method for on-wafer testing of optical structures of photonic chips that include edge couplers as input/out ports includes defining, in test a test area of the wafer, an edge coupler pair formed of two edge couplers separated by a test gap, which may have a width that is close to the width of a chip-fiber gap during normal operation of the photonic chips. Test areas may include chains of different numbers of the edge coupler pairs for determining coupling loss per edge coupler.

### FIELD OF THE INVENTION

The invention generally relates to photonic integrated circuits, and more particularly relates to methods, devices, and structures for on-wafer testing of photonic chips.

### BACKGROUND OF THE INVENTION

Optical devices that are commonly used in optical communication systems are typically fabricated as photonic integrated circuits (PIC). A significant expense in the production of PICs is test during manufacture. Typically multiple instances of a PIC are fabricated on a single wafer and usually need to be diced into many separate photonic chips that are then tested individually. When manipulating the chips individually there is the possibility of damaging the chip. Some packaging may also be needed, such as wire bonding or fiber attach, before testing can occur. Testing discrete chips that need processing before evaluating for failure is a costly process. A preferred method is to test each system on wafer before dicing the wafer into individual chips. However, conventional approaches to on-wafer testing may involve testing conditions that differ from the conditions in which individual photonic chips operate.

There is a need for improved systems and methods for testing and qualifying photonic chips.

### SUMMARY OF THE INVENTION

An aspect of the present disclosure relates to a method for on-wafer characterization of optical structures of photonic chips defined in a photonic wafer, the photonic chips being spaced apart on the photonic wafer and comprising each an edge coupler, the method comprising: defining one or more test areas upon the photonic wafer, and in each of the one or more test areas, providing a test structure comprising one or more edge coupler pairs (ECPs), each edge coupler pair comprising two test edge couplers optically coupled across a test gap that is at most half in width of a spacing separating adjacent photonic chips on the wafer.

According to a feature of the present disclosure, the method may comprise forming the test gap between the two test edge couplers having a width that is substantially equal to a nominal coupling distance to an external optical waveguide during normal operation of the photonic chip in an optical system after separation from the photonic wafer, thereby making it more suitable for determining the performance of the photonics chips at wafer level prior to dicing, as compared to wafer-scale testing across dicing lines or single-chip measurements after dicing.

In at least some implementations the method may comprise: forming, in the one or more test areas, a photonic integrated circuit (PIC) test structure including a test instance of a PIC of one of the photonic chips; disposing a test edge coupler across the test gap from the edge coupler test instance of the PIC so as to form one of the ECPs; and, disposing an input test port for coupling test light into the test edge coupler for propagating through the test gap of the first ECP into the edge coupler of the test instance of the PIC.

In at least some implementations the method may comprise forming, in the one or more test areas, two or more test structures, each of the two or more test structures comprising an input port, an output port, and a chain of the edge coupler pairs connected in series therebetween, wherein each of the chains comprises a different number of the edge coupler pairs. The method may further include measuring optical loss of each of the two or more test structures, and estimating a coupling loss of one edge coupler from a dependence of the measured optical losses of the two or more test structures on the number of edge coupler pairs therein.

An aspect of the present disclosure relates to a photonic wafer comprising: a substrate; an optical layer supported by the substrate; a plurality of photonics chips defined upon the substrate so as to be spaced apart from each other by at least a first distance, each photonic chip comprising an edge coupler that is defined at least in part in the optical layer and configured to be used for coupling light into or out of the optical layer of the photonic chip when the photonic chip is separated from the wafer; and, one or more test structures defined at least in part in the optical layer, each comprising one or more edge coupler pairs (ECPs), each of the one or more ECPs comprising two test edge couplers optically coupled across a test gap, wherein the test gap separates the two test edge couplers by a second distance that is at most half the first distance.

### BRIEF DESCRIPTION OF THE DRAWINGS

Embodiments disclosed herein will be described in greater detail with reference to the accompanying drawings, which may be not to scale and in which like elements are indicated with like reference numerals, and wherein:

FIG. 1 is a schematic plan view of a portion of a photonic wafer incorporating test structures;

FIG. 2 is a schematic side view of a photonic chip with an edge coupler butt-coupled to an optical fiber;

FIG. 3 is a plot showing coupling loss between two example edge couplers formed in a SiN layer in dependence on a width of a SiO2 gap therebetween; the example edge couplers are designed for a 5 μm mode size at the coupling end;

FIG. 4A is a schematic diagram illustrating a plan view of a coupling portion of an edge coupler test structure with two edge couplers separated by a narrow gap;

FIG. 4B is a schematic diagram illustrating the coupling portion of the edge coupler test structure of FIG. 3A in a longitudinal cross-section thereof across a trench forming the test gap;

FIG. 5 is a schematic diagram illustrating, in a plan view, test structures including chains of edge coupler pairs of varying length for measuring optical loss per coupler;

FIG. 6 is an example plot conceptually illustrating the insertion loss of the chains of the edge coupler pairs versus the number of the edge coupler pairs in the chain;

FIG. 7A is a schematic diagram illustrating test structures for polarization-dependent measurements of edge coupler loss using TE and TM grating couplers;

FIG. 7B is a schematic diagram illustrating a test structure with a TE grating coupler and a polarization rotator for measuring TM mode loss of edge couplers;

FIG. 8 is a schematic plan view of a photonic chip with a PIC that includes a photonic device for performing a function and two edge couplers for coupling to an outside circuit when separated from the wafer;

FIG. 9 is a schematic a plan view of a test structure for testing the PIC of the photonic chip of FIG. 8;

FIG. 10 is a schematic plan view of an edge coupler test structure for characterizing collimating edge couplers;

FIG. 11 is a schematic plan view of a multi-tip edge coupler with two guard stripes shielding a central waveguide;

FIG. 12 is a schematic plan view of an embodiment of the multi-tip edge coupler of FIG. 11 with the guard stripes in the form of inverted tapers designed to facilitate optical coupling with a center waveguide taper;

FIG. 13 is a schematic plan view of a test edge coupler pair for characterizing multi-tip edge couplers of FIG. 12.

### DETAILED DESCRIPTION

In the following description, for purposes of explanation and not limitation, specific details are set forth, such as particular optical circuits, circuit components, techniques, etc. in order to provide a thorough understanding of the present invention. However, it will be apparent to one skilled in the art that the present invention may be practiced in other embodiments that depart from these specific details. In other instances, detailed descriptions of well-known methods, devices, and circuits are omitted so as not to obscure the description of the present invention. All statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Furthermore, the following abbreviations and acronyms may be used in the present document:

GaAs Gallium Arsenide

InP Indium Phosphide

PIC Photonic Integrated Circuit

SOI Silicon on Insulator

MUX Multiplexer

PDL Polarization Dependent Loss

IL Insertion Loss

TE Transverse Electric (mode)

TM Transverse Magnetic (mode)

In the following description, the term “light” refers to electromagnetic radiation with frequencies in the visible and non-visible portions of the electromagnetic spectrum. The term “optical” relates to electromagnetic radiation in the visible and non-visible portions of the electromagnetic spectrum. The terms “first”, “second” and so forth are not intended to imply sequential ordering, but rather are intended to distinguish one element from another, unless explicitly stated. Similarly, sequential ordering of method steps does not imply a sequential order of their execution, unless explicitly stated. The word ‘using’, in a description of a method or process performed by an element, circuit, or device, refers to an action performed by the element, circuit, or device itself or by a component thereof rather than by an external agent, unless is explicitly stated otherwise. As used herein the term “substrate” encompasses a silicon wafer, a silicon on insulator (SOI) wafer, a semiconductor wafer comprising material such as III-V compounds such as GaAs, InP and alloys of such III-V compounds, and wafers made of materials that are not semiconducting such as quartz and alumina.

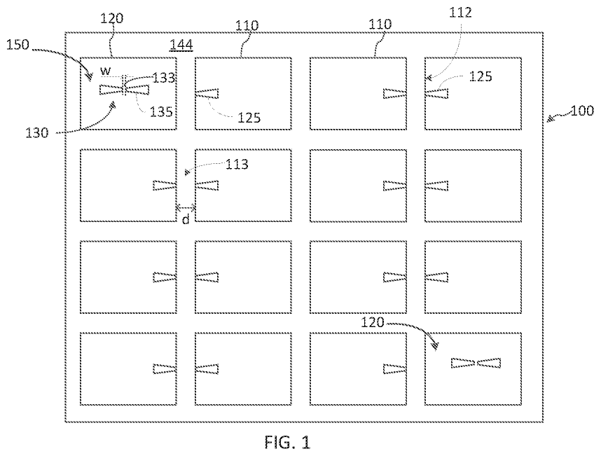

Referring to FIG. 1, there is illustrated a portion of a wafer 100 having at least one optical layer 150 where light can propagate, the optical layer supported by a substrate 144, and a plurality of photonic chips 110 defined in the wafer. The portion of wafer 100 illustrated in FIG. 1 may represent, for example, one reticle of the wafer. Each of the photonic chips 110 includes at least one edge coupler 125 disposed with a coupling end adjacent to an edge of the photonic chip and configured for connecting to an outside optical circuit when the corresponding chip 110 is separated from wafer 100. Each of the chips 110 may also include one or more optical waveguides and/or optical devices, which are not shown in the figure and which may form a photonic integrated circuit (PIC) with the edge coupler 125. Adjacent photonic chips 110 are spaced apart from each other by a gap or edge-to-edge spacing 113 of width d, which may also be referred to herein as the first distance, and which is typically big enough to allow for dicing of the wafer to separate the chips. By way of example, the width d of the inter-chip gap or spacing 113, i.e. the first distance, may be at least 50 microns (μm), and more typically 100 μm or more. The inter-chip gap or spacing 113 may be in the form of, or include, a dicing lane so that the chips 110 can be cut out of the wafer 100. In some embodiments gaps 113 may be etched to separate the chips. The width d of the inter-chip gap or spacing 113 defines a minimum spacing between edge couplers 125 of adjacent photonic chips 110. Wafer 100 further includes at least one test area 120 that includes at least one edge coupler pair (ECP) 130 that is formed of two optically aligned test edge couplers 135 oriented with their coupling ends facing each other across a test gap 133 so as to be optically coupled. The test gap 133 separates the two test edge couplers 135 by a second distance w which may also be referred to as the width of the test gap 133. In some embodiments the second distance w, i.e. the width of the test gap 133, is at most half of the first distance d, i.e. the width of the inter-chip spacing 113. In some embodiments wafer 100 may include multiple reticles, or multiple wafer areas, at least some of which including multiple chips 110 and one or more test area 120. The test area 120 may be a sacrificial area of the photonic wafer that may be discarded after testing and is generally not for use as a light processing device in any optical system other than for the purpose of the photonic chip testing. In some embodiment the test gap 133 may be in the form of a trench etched in the wafer at a stage of manufacturing where the waveguides are defined in an optical layer of the wafer, and may be filled at a later wafer manufacturing step with a dielectric material of the upper cladding layer, for example silicon dioxide SiO2 or silicon nitride Si3N4 in SOI-based strictures. In other embodiments the trench may be etched at a later stage of manufacturing.

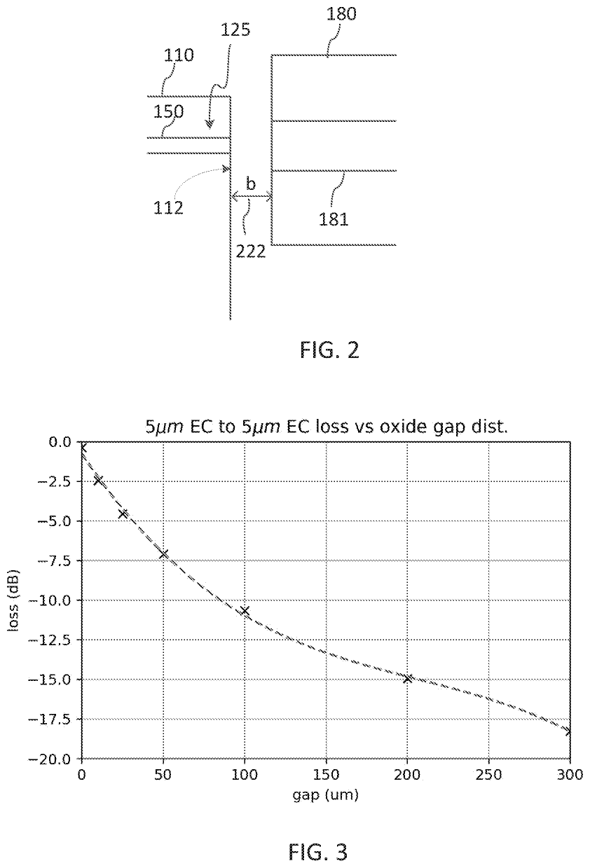

In some embodiments edge couplers 125 of adjacent chips may be aligned across the gap 113, and could potentially be used for on-wafer testing of optical coupling therebetween, as described for example in [parent application], which is incorporated herein by reference. However, this approach may have drawbacks if the photonic chips 110 are to be closely butt-coupled to external waveguides during normal operation of the chips after their separation from the wafer. An example of such butt-coupling is illustrated in FIG. 2, which shows a vertical cross-section of an end portion of a photonic chip 110 butt-coupled to an optical fiber 180 with a core 181. An edge coupler 125, which may be defined in the optical layer 150 of the chip, terminates at a facet 112 of the chip, where it faces a waveguiding core 181 of the optical fiber 180 across a coupling gap 222. The width b of this coupling gap is typically in the range of 1 to 10 μm in most applications. This is much smaller than the inter-chip gap or spacing 113 on wafer or reticle 100, as the later has to be large enough to accommodate dicing. However, coupling loss quickly increases as the coupling gap rises, as illustrated by way of example in FIG. 3, which shows simulation results for a coupling loss between two edge couplers in dependence on the width of a coupling gap separating them. The simulations were performed for example edge couplers formed in a silicon nitride (SiN) layer of a SOI structure and designed to have a 5 μm wide optical mode at the coupling tips; it will be appreciated however that the approach described herein is equally applicable is not limited to such couplers and is equally applicable to any other edge coupler design as well.

Thus, on-wafer measurements of optical coupling between two edge couplers 125 across the inter-chip spacing 113 may not provide a fair estimate of the fiber-chip optical coupling during normal operation of a photonic chip 110 after the chip is separated from the wafer. Accordingly, an aspect of the present disclosure provides the edge-coupler pair 130 to be placed in one or more test areas 120 of wafer or reticle 100, in which two edge couplers 135 are optically aligned facing each other over the test gap 133 which is much narrower in width than the inter-chip spacing 113. In some embodiments the test gap 133 may be substantially same or similar to the coupling gap 222 between chip 100 and an external waveguide 180 that is expected during normal operation of the chip 110 in an optical system. Here the term “substantially equal” may mean equal to within +/−50% of a target width of the coupling gap 222. In some embodiments wafer or reticle 100 may include a plurality of test areas 120, which may include same or different test structures, and may be spread around the wafer or reticle to provide information on spatial variations of various relevant parameters across the wafer or reticle. FIG. 1 shows by way of example two test areas 120 disposed across a wafer's diameter.

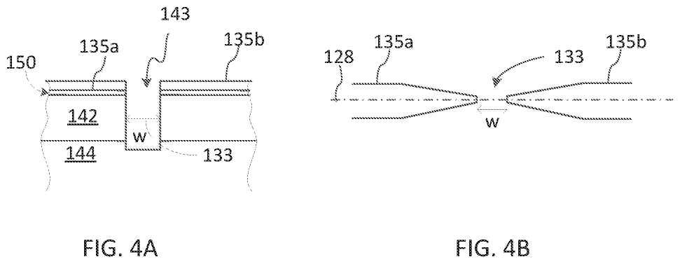

Referring to FIGS. 4A and 4B, they illustrate possible embodiments of the edge-coupler pair 130 in further detail. FIG. 3A illustrates a central portion of the edge coupler pair 130 in a longitudinal cross-section along an optical axis 128 thereof illustrated in FIG. 4B. FIG. 4A shows the optical layer 150 in which the test edge couplers 135a,b are fabricated, and a trench 143 of width w that separates them to form the test gap 133. The trench 143 may be fabricated for example by etching through the optical layer 150 to a desired depth. In one embodiment the depth of the trench may be selected so as to reduce optical coupling between the test couplers 135a, 13b through a lower cladding 142. By way of example, the optical layer 150 may have a thickness between about 1 μm to 0.1 μm, typically 0.2-0.5 μm, and the trench 133 may be about 5-20 μm deep with the width w of 1-10 μm, or 3 to 7 μm in some embodiments. In some embodiments the trench may be filled at a later wafer manufacturing steps with a dielectric material. In SOI-based embodiments this dielectric material may be for example silicon dioxide SiO2, but could also be silicon nitride Si3N4. In one embodiment the optical layer 150 may be formed in a silicon layer of a SOI wafer, with a lower cladding 142 of SiO2 disposed over a silicon substrate 144. In another embodiment the optical layer 150 may be formed in a S3N4 layer disposed between layers of silicon dioxide forming the cladding layers.

FIG. 4B shows a central portion of the edge coupler pair 130 in a plan view, in an embodiment wherein the trench 143 of FIG. 4A is filled with the same material that surrounds the cores of the test edge couplers 135a, 135b to form the test gap 133. The two test edge couplers 135a, 135b are optically aligned with their coupling tips facing each other across the test gap 133. Each of the edge couplers 135a, 135b may be substantially identical in structure to the edge couplers 125 of photonic chips 110, i.e. fabricated to same specifications in terms of their geometry, material, and size, and are optically aligned with a common optical axis 128. By way of example, in one embodiment the test edge couplers 135a, 135b are formed in a SiN layer of a SOI wafer surrounded by SiO2. The thickness of the SiN layer may be, for example, 0.3 μ and taper each from a nominal waveguide width of 0.8 μ to 0.3 μ at the coupling tips over a length of 120 μ which are separated by the test gap 133 of SiO2 that may be 1 to 10 μm wide, or 3 to 7 μm in some embodiments. Such a structure provides about 5 μ wide optical mode at the coupling tip of each coupler.

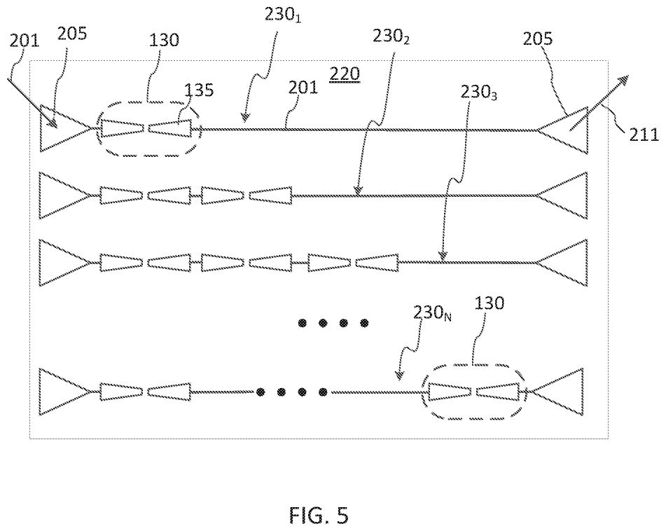

Referring now to FIG. 5, there is illustrated a sequence of N test structures 230₁-230_{N} that may be formed in one or more test areas 220 of wafer 100. Each of the test structures 230₁-230_{N}, which may be generally referred to as test structures 230, includes a sequence of one or more edge coupler pairs 130 optically connected in series between two test ports 205, one of which may serve as the input test port and the other as the output test port. In some embodiments the test ports 205 may be configured for coupling test light in and out of the optical layer of the wafer, and more particularly to couple the test light, for example from a source outside of the wafer, into a corresponding chain of one or more of the edge coupler pairs 130, and to direct the test light to an external measurement system (not shown) after the propagation through the chain of the one or more edge coupler pairs 130. Note that the solid lines connecting various elements of each test structure 230 represent optical connections, that may be for example in the form of optical waveguides, which may be generally of the same width as the ends of the test edge couplers 135 to which they connect. In one embodiment the test ports 205 may each be in the form of a grating coupler configured to couple confined transverse modes of the optical layer 150, or of optical waveguides connecting the ports to the test edge couplers, with radiative modes, so that the test light may be injected into the test structures 230 from a source outside of the chip, and can then be extracted from the chip to me measured after propagating through the test structure. Thus the test light 211 incident upon one of the grating couplers 205 at an angle may then be redirected by that grating coupler to propagate through one or more edge coupler pairs 130 in sequence, to be is extracted from the chip by the output grating coupler 205. Accordingly in each of the test structures 230, the grating couplers 205 at one of the opposing ends thereof may operate as an input test port, and the other—as the output test port.

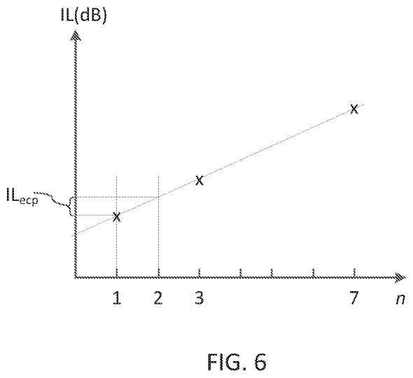

Continuing to refer to FIG. 5, it illustrates an example embodiment wherein one test area of wafer or reticle 100 includes a sequence of test structures 230 with successively increasing number of serially connected edge coupler pairs, so that the shortest test structure 230₁ includes one edge coupler pair 130, and the longest test structure 230_{N} includes N edge coupler pair 130 optically connected in series, where N is at least 2 or more. By directing the test light 201 of known optical power into the input ports 205 of each of the test structures 230 and measuring the output optical power of the output test light 211, an average insertion loss (IL) per one edge coupler pair IL_{ecp} may be determined as a slope of the dependence of the total IL of a test structure 230 versus the number n of the edge coupler pairs therein. This is schematically illustrated in FIG. 6, where the IL of three test structures 230 having 1, 3, and 7 edge coupler pairs shown by ‘x’, and the IL per edge coupler pair IL_{ecp} is indicated.

In other embodiments the test structures 230 may be spread among different test areas of a wafer, and the edge coupler pairs 130 may be distributed in differing numbers among the test structures 230, so that there are at least two test structures 230 that include different numbers of the edge coupler pairs 130. Note that since a linear function may be defined by two data points, generally it may be sufficient to have two test structures 230 with two different numbers of the edge coupler pairs therein, which may be referred to herein as the first and second test structures, but a greater number of the test structures 230 which chains of edge coupler pairs 130 of different lengths may be preferred for greater accuracy. Note also that FIG. 4 shows test structures 230 with different numbers of ECPs 130 having a same physical length. This enables aligning their input and output ports, which may simplify automatic IL measurements of the structures. However, this necessitates having different lengths of connecting waveguides per ECP in different test structures, which may introduce an error if the waveguide loss is significant. Accordingly, in other embodiments the length of connecting waveguides in each test structure 230 may scale with the number of ECPs in the chain, so that test structures 230 with fewer ECPs are shorter. Note that in the context of this specification the length of a test structure is understood as a physical length thereof, while the length of a chain of ECPs is understood to mean the number of ECPs in the chain.

Advantageously, having different-length chains of edge coupler pairs sandwiched between two test ports enables a rather accurate measurement of an insertion loss per one edge coupler pair. Furthermore, in a typical embodiment edge couplers 125 and 135 may be optimized for coupling to an external waveguide, such as an optical fiber, of a specific configuration and assuming a specific coupling arrangement, for example butt-coupling. More particularly, the edge couplers 125 and 135 may be optimized to match the mode field diameter of the external waveguide. Accordingly, the insertion loss IL_{ec} measure per one ECP 130 as described hereinabove may be a good approximation to the IL associated with coupling of an optical chip 110 to the external waveguide, provided that the width of the test trench 133 separating the test edge couplers in each ECP 130 is approximately equal, up to the wafer processing accuracy, for example within +/−50% or preferably within +/−10%, to a nominal value of the butt-coupling distance 222. Here, the term “nominal” refers to a target value of a corresponding parameter that may be defined by a system or chip design.

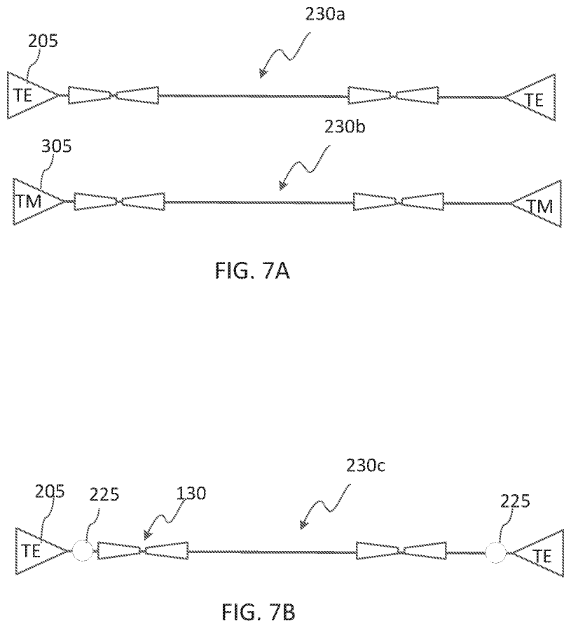

Turning now to FIG. 7A, there are illustrated test structure 230a, 230b that may be used for measuring the IL of a ECP 130 for TE and TM polarized light, which enables to estimate an average polarization dependent loss (PDL) of one ECP. Each of the test structure 230a-230c is shown to include the same number of ECPs 130, two by way of example only. In the test structure 230a they are connected between grating compliers 205 that are configured to convert input test light into a TE mode of the optical waveguide of the test structure, so that the IL of the test structure is measured for the TE mode propagation. In the test structure 230b they ECPs are connected between grating compliers 305 that are configured to convert input test light into a TM mode of the optical waveguide of the test structure, so that the IL of the test structure is measured for the TM mode propagation. The insertion loss per ECP for the TM mode propagation may also be assessed using a test structure 230c illustrated in FIG. 7B, which includes two grating couplers 205 configured to operate in the TE mode, which connect to polarization rotators 225 that convert the TE mode into the TM mode prior to directing it into the ECPs, and then convert the TM mode back into the TE mode before directing it to the output TE grating coupler 205. By performing the measurements of the type described hereinabove with reference to FIGS. 5 and 6 for both the TM and TE modes, the average PDL pre edge coupler connection may be estimated.

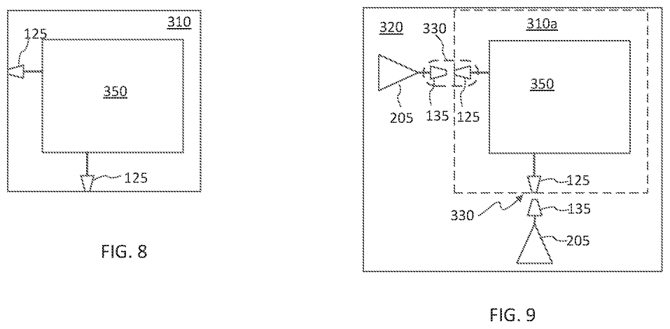

Referring now to FIG. 8, there is schematically illustrated a layout of an example photonic chip 310 that may embody any of the photonic chips 110 of FIG. 1. Photonic chip 310 includes a photonic integrated circuit (PIC) composed of two edge couplers 125 that connect optically to a photonic device 350, which may embody a desired functionality. By way of example, photonic device 350 may embody an optical front-end of a coherent optical receiver and may include an optical mixer, with one of the edge couplers 125 configured to be coupled to an optical fiber of an optical communication link to receive signal light, and the other edge coupler 125 configured to be coupled to an optical fiber of waveguide providing local oscillator (LO) light.

Turning now to FIG. 9, there is schematically illustrated an example layout of a test area 320 of a wafer or reticle 100 that is configured for on-wafer testing of the photonic circuit of chip 310. The test area 320 includes a PIC test structure formed of a test instance 310a of the photonic circuit of chip 310, and two test ports 205 for receiving or outputting test light that may be for example in the form of grating couplers. The grating couplers 205 connect optically, for example with suitable optical waveguides, to two test edge couplers 135, which are disposed to be optically coupled to respective edge couplers 125 of the photonic circuit 310a across the test trenches so as to form two ECPs 330, as generally described hereinabove with reference to FIGS. 1-5. In each EPC 330 of FIG. 9, the respective edge coupler 125 of the test PIC 310a forms a first test edge coupler of the EPC 330, while the additional edge coupler 135 forms the second test edge coupler of the EPC 330. The ECPs 130 enable to inject test light into the photonic circuit 310a in conditions closely approximating those during normal operation thereof thanks to the design of ECPs 130 as described hereinabove, and therefore enable on-wafer testing of an instance of the photonic circuit of a chip in conditions approximating those encountered by photonic chips 310 during their normal operation after being separated from the wafer. It will be appreciated that in other embodiments the photonic chip 310 may have more than two edge couplers 125 or only one edge coupler 125, in which case the number of test couplers 135 and of the ECPs 130 formed will change accordingly.

Advantageously, this approach may be used to test, on the wafer scale, the performance of actual PICs as they would behave during normal operation with edge couplers as optical interfaces. Among other things, it enables simultaneous on-wafer testing of multiple optical facets of a chip,—such as an edge coupled optical fan-out, which would otherwise be very difficult to characterize at chip level. This approach therefore may drastically reduce test time and improve test accuracy, while allowing for more complex edge coupled systems to be tested.

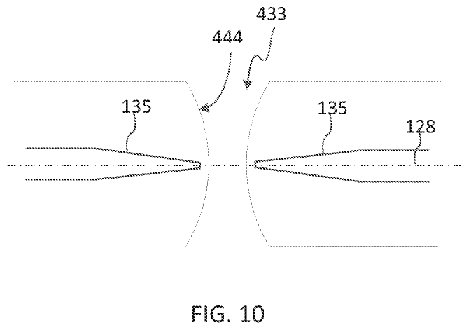

Referring now to FIG. 10, there is illustrated yet another example embodiment of a ECP 130 in which two edge couplers 135 formed of waveguide tapers face each other across a test trench 433 that widens away from an optical axis 128 of the edge coupler pair so as to at least partially collimate or focus light propagating between the two test edge couplers 135. Other embodiments may include other types of edge couplers, including but not limited to those formed of straight waveguides and waveguide tapers that widen towards their termination at an edge of a chip.

Note that FIGS. 1, 4B-10 described hereinabove show a specific type of an edge coupler that is formed of a waveguide taper that narrows towards the coupling end; such edge couplers may be advantageously formed in high-contrast silicon waveguides, wherein the optical confinement of the waveguide mode relaxes as the waveguide narrows, and the mode expands to better match the fundamental mode of a typical optical fiber. It will be appreciated however that the exact shape and design of the edge couplers 125, and the corresponding test couplers 135, may vary depending on application, material system of the wafer, the type and material of external waveguides to which the edge couplers are to be coupled during normal operation, and other circumstances, and the approaches and techniques described hereinabove with reference to the example embodiments may also be readily extended to encompass others types of edge couplers.

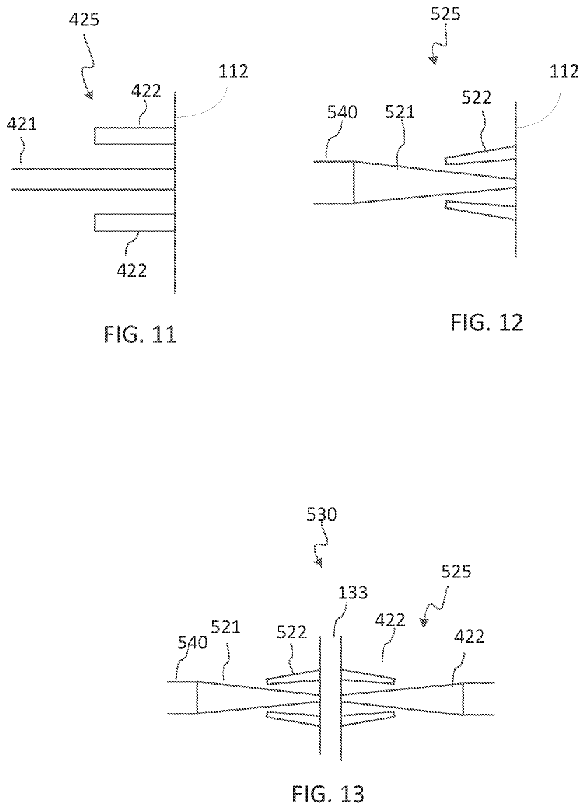

Referring to FIG. 11, there is illustrated an edge coupler 425 that is formed by an end coupling portion of a waveguide 421 terminating at a chip edge 112 and two guard stripes 422 that are formed in the same optical layer as the main waveguide 421. The guard stripes 422 may be disposed symmetrically from the main input/output waveguide 421 at both sides thereof, may also terminate at the chip edge 112, but may not connect to any optical waveguide. The guard stripes 422 effectively shield the end coupling portion of the main waveguide 421 from the rest of the chip layout, thereby making the coupling performance of the edge coupler 425 more predictable and less dependent on immediate neighbors of the edge coupler 425. The spacing between the guard stripes 422 and the central waveguide 421 may be, for example, in the range of 0.5-3 μm, and in some embodiments preferably 1-2 μm, but may vary depending on the waveguide materials and the operating wavelength range.

Although in FIG. 11 the end coupling portion of the main waveguide 421 is schematically shown to be of a constant width, in other embodiments it may have a different shape, and may be tapered. Coupling efficiency of an edge coupler in the form of a waveguide taper that narrows towards its coupling end may be particularly sensitive to the exact dimension of the tip of the waveguide taper, which in fabrication may vary in dependence on other layout features that may be present in the vicinity of the edge coupler.

Referring to FIG. 13, there is illustrated an edge coupler 525 that is formed of a central waveguide taper 521 connecting to an optical waveguide 540, and two guard stripes 522 in the form of side tapers 522 that shield the central waveguide taper 521 from the rest of the chip layout, thereby making the coupling efficiency of the edge coupler 525 less dependent on its placement within the chip and on chip's layout. Furthermore, when placed within dimensions of the optical mode of the main waveguide taper 521, the guars tapers 522 may be configured so as to improve coupling efficiency of the edge coupler. In some embodiments they may be in the form of an inverted taper, widening towards the coupling end of the edge coupler 525 at the chip edge 112. In some embodiments the guard stripes 522 may also be oriented so as to fan out towards the coupling end of the edge coupler. Both these features may facilitate optical coupling of input light into the central taper 521 and, ultimately, into the optical waveguide 540.

Referring now also to FIG. 12, in embodiments wherein photonic chips defined in a wafer use edge couplers in the form of the shielded three-tip edge coupler 425, 525, or a variation thereof, test edge couplers may also be of the same three-tip shielded design. By way of example, in embodiments of wafer 100 in which edge couplers 125 are in the form of three-tip edge couplers 525 of FIG. 12, ECPs 130 described hereinabove are in the form of ECP 530 and are formed of two shielded edge couplers 525 facing each other across the test gap 133.

According to example embodiments disclosed above in reference to FIGS. 1-13, provided is a photonic wafer comprising: a substrate (e.g. substrate 144, FIGS. 1 and 4A); an optical layer (e.g. optical layer 150, FIGS. 1, 2, 4A) supported by the substrate; a plurality of photonics chips (e.g. 110, FIG. 1, 310, FIG. 8) defined upon the substrate so as to be spaced apart from each other, each photonic chip comprising an edge coupler (e.g. 125, 425, 525) that is defined at least in part in the optical layer and configured to be used for coupling light into or out of the photonic chip when the photonic chip is separated from the wafer; and, one or more test structures (e.g. 230₁, 230₂, 230₃, 230_{N}, 230a, 230b, 230c, FIG. 9) defined at least in part in the optical layer, each comprising one or more edge coupler pairs (ECPs) (e.g. 130, 330), each of the one or more ECPs comprising two test edge couplers (e.g. 135) optically coupled across a test gap (e.g. 133, 433), wherein the test gap separates the two test edge couplers (e.g. 135) by a distance w that is at most half i of a spacing (e.g. 113) between adjacent photonic chips.

In some embodiments at least one of the two test edge couplers is substantially identical in structure to the edge couplers of the photonic chips.

In some embodiments the one or more test structures comprise a first test structure (e.g. 230₁, 230₂, . . . ) comprising an input test port (e.g. 205, FIG. 5), an output test port (e.g. 205), and a number of the ECPs optically connected in series therebetween.

In some embodiments at least one of the input and output test ports comprises a grating coupler.

In some embodiments the one or more test structures are disposed in a plurality of test areas (e.g. 120, 220, 320) spread across the substrate.

In some embodiments the photonic wafer may include a second test structure (e.g. 230₃) comprising an input test port, an output test port, and a number of the ECPs optically connected in series therebetween, wherein the number of the ECPs in the second test structure differs from the number of the ECPs in the first test structure (e.g. 230₁ or 230₂).

In some embodiments at least one of the photonic chips (e.g. 310, FIG. 8)) comprises a photonic integrated circuit (PIC) (e.g. 350) including the edge coupler of the photonic chip (e.g. 125 FIG. 8), and wherein the one or more test structures comprises a PIC test structure disposed in a test area of the wafer (e.g. 320, FIG. 9), wherein the one or more EPCs of the PIC test structure comprise a first EPC (e.g. 330), the PIC test structure further including: a test instance of the PIC (e.g. 310a), with the edge coupler thereof (e.g. 125) forming a first test edge coupler of the two test edge couplers of the first EPC; and, an input test port (e.g. 205 FIG. 9) for coupling test light into a second of the two edge couplers (e.g. 135) of the first EPC for propagating through the test gap of the first EPC into the edge coupler of the test instance of the PIC (e.g. 125 FIG. 9).

In some embodiments the spacing (e.g. 113, FIG. 1) separating adjacent photonic chips is at least 50 microns wide and the test gap (e.g. 133) is at most 10 microns wide.

In some embodiments the edge couplers of the photonic chips and at least one of the test edge couplers (e.g. 425, 525) of the one or more EPCs comprise each a center waveguide taper (e.g. 421, 521, FIGS. 11-13) disposed between two guard stripes (e.g. 422, 522, FIGS. 11-13. configured to shield the center waveguide taper from the rest of the chip. In some embodiments the guard stripes are shaped as inverted tapers that widen towards a coupling end of the edge coupler. In some embodiments the guard stripes fan out towards a coupling end of the edge coupler.

In some embodiments the test gap (e.g. 433, FIG. 10) widens away from an optical axis of the edge coupler pair so as to at least partially collimate or focus light propagating between the two test edge couplers thereof.

In some embodiments the edge couplers of the photonic chips are configured for butt coupling to an optical waveguide (e.g. 180, FIG. 2), and wherein the width of the test gap (e.g. 133, 433) is substantially equal to a nominal distance (e.g. 222) between the photonic chip and the optical waveguide in the butt coupling.

Example embodiments disclosed above with reference to FIGS. 1-13 provide further a method for on-wafer characterization of optical structures of photonic chips (e.g. 110, 310) defined in a photonic wafer (e.g. 100), the photonic chips being spaced apart on the photonic wafer and comprising each an edge coupler, the method comprising: defining one or more test areas (e.g. 120, 320) upon the photonic wafer, and in each of the one or more test areas, providing a test structure (e.g. 230₁, 230₂, 230₃, 230_{N}, 230a, 230b, 230c, FIG. 9) comprising one or more edge coupler pairs (ECPs) (e.g. 130, 330, 530, each edge coupler pair comprising two test edge couplers optically coupled across a test gap that is at most half in width of a spacing separating adjacent photonic chips on the wafer.

In some embodiments of the method the edge coupler of the photonic chips are configured for coupling to an external optical waveguide that is spaced by a pre-defined nominal coupling (e.g. 222, FIG. 2) distance from an edge of the photonic chip, the method comprising forming the test gap (e.g. 133, 433) between the two test edge couplers (e.g. 125, 425, 525) having a width that is substantially equal to the nominal coupling distance (e.g. 222) to the external optical waveguide.

In some embodiments the method comprises forming, in the one or more test areas (e.g. 220, FIG. 5), two or more test structures (e.g. 230₁, 230₂, 230₃, . . . ), each of the two or more test structures comprising an input port (e.g. 205), an output port (e.g. 205), and a chain of the edge coupler pairs (e.g. 130) connected in series therebetween, wherein each of the chains comprises a different number of the edge coupler pairs.

In some embodiments the method comprises measuring optical loss of each of the two or more test structures (e.g. 230₁, 230₂, 230₃, . . . ), and estimating a coupling loss of one edge coupler from a dependence of the measured optical losses of the two or more test structures on the number of edge coupler pairs therein.

In some embodiments of the method at least one of the photonic chips comprises a photonic integrated circuit (PIC) (e.g. 310, FIG. 8) including the edge coupler of the photonic chip, and the method comprises: forming, in the one or more test areas (e.g. 320), a PIC test structure including a test instance of the PIC (e.g. 310a); disposing a test edge coupler (e.g. 135) across the test gap from the edge coupler (125) of the test instance of the PIC so as to form one of the ECPs (330); and, disposing an input test port e.g. 205) for coupling test light into the test edge coupler for propagating through the test gap of the first EPC (e.g. 330) into the edge coupler (e.g. 125) of the test instance of the PIC.

The above-described exemplary embodiments are intended to be illustrative in all respects, rather than restrictive, of the present invention. Indeed, various other embodiments and modifications to the present disclosure, in addition to those described herein, will be apparent to those of ordinary skill in the art from the foregoing description and accompanying drawings.

For example, it will be appreciated that different dielectric materials and semiconductor materials other than silicon, including but not limited to compound semiconductor materials of groups commonly referred to as A3B5 and A2B4, such as GaAs, InP, and their alloys and compounds, may be used to fabricate the optical circuits example embodiments of which are described hereinabove. Furthermore, in some embodiments the two test couplers forming an edge coupler pair may differ in their design; for example a photonic chip may be designed for different types of optical coupling to an external system, including coupling to optical waveguides of different mode size, and the on-wafer test structures may include edge coupler pairs that vary in the design of at least one of the two test edge couplers. Furthermore, one or both of the test ports 205 may be in a form other than coupling grating; for example an output test port may be in the form, or include, a photodetector, while an input test port may be in the form, or include, a light source such as an LED or a laser diode. The test ports 205 may also be in the form of an edge coupler. Furthermore, in some embodiments measurements on test structures described hereinabove may be performed after dicing of the wafer into separate chips, or after the test areas are separated from the wafer. It will be understood by one skilled in the art that various other changes in detail may be affected therein without departing from the spirit and scope of the invention as defined by the appended claims.

1. A photonic wafer comprising:
a substrate;
an optical layer supported by the substrate;
a plurality of photonics chips defined upon the substrate so as to be spaced apart from each other, each photonic chip comprising an optical device and an edge coupler that are defined at least in part in the optical layer, wherein the edge coupler is configured to be used for coupling light in or out of the optical device when the photonic chip is separated from the wafer; and,
a first test structure[[s]] defined at least in part in the optical layer, the first test structure comprising one or more edge coupler pairs (ECPs), each of the one or more ECPs comprising two test edge couplers optically coupled across a test gap, wherein the test gap separates the two test edge couplers by a distance that is at most half of an edge-to-edge spacing between adjacent photonic chips, and wherein neither of the two test edge couplers is configured to be used as an edge coupler of a photonic chip after the photonic chips are separated from the photonic wafer.

2. The photonic wafer of claim 1 wherein at least one of the two test edge couplers is substantially identical in structure to the edge couplers of the photonic chips.

3. The photonic wafer of claim 1 wherein the first test structure comprises an input test port, an output test port, and a plurality of the ECPs optically connected in series between the input test port and the output test port in the absence of optical components therebetween other than waveguide interconnects.

4. The photonic wafer of claim 3 wherein at least one of the input and output test ports comprises a grating coupler.

5. The photonic wafer of claim 1 comprising a plurality of the first test structures that are disposed in a plurality of test areas spread across the substrate.

6. The photonic wafer of claim 3 further including a second test structure comprising an input test port, an output test port, and a plurality of the ECPs optically connected in series between the input test port and the output test port of the second test structure in the absence of optical components therebetween other than waveguide interconnects, wherein the number of the ECPs in the second test structure differs from the number of the ECPs in the first test structure.

7. The photonic wafer of claim 1 wherein the one or more ECPs comprise a first ECP, and wherein the first test structure comprises:
a test instance of the optical device optically connected to a first test edge coupler of the two test edge couplers of the first ECP; and,
an input test port for coupling test light into a second edge coupler of the two edge couplers of the first ECP for propagating through the test gap of the first ECP into the edge coupler of the test instance of the optical device.

8. The photonic wafer of claim 1 wherein the edge-to-edge spacing separating adjacent photonic chips is at least 50 microns wide and the test gap is at most 10 microns wide.

9. A photonic wafer comprising:
a substrate;
an optical layer supported by the substrate;
a plurality of photonics chips defined upon the substrate so as to be spaced apart from each other, each photonic chip comprising an edge coupler that is defined at least in part in the optical layer and configured to be used for coupling light into or out of the photonic chip when the photonic chip is separated from the wafer; and,
one or more test structures defined at least in part in the optical layer, each comprising one or more edge coupler pairs (ECPs), each of the one or more ECPs comprising two test edge couplers optically coupled across a test gap, wherein the test gap separates the two test edge couplers by a distance that is at most half of an edge-to-edge spacing between adjacent photonic chips;
wherein the edge couplers of the photonic chips and at least one of the test edge couplers of the one or more ECPs comprise each a center waveguide taper disposed between two guard stripes configured to shield the center waveguide taper from the rest of the chip.

10. The photonic wafer of claim 9 wherein the guard stripes are shaped as inverted tapers that widen towards a coupling end of the edge coupler.

11. The photonic wafer of claim 9 wherein the guard stripes fan out towards a coupling end of the edge coupler.

12. The A photonic wafer of claim 1 comprising:
a substrate;
an optical layer supported by the substrate;
a plurality of photonics chips defined upon the substrate so as to be spaced apart from each other, each photonic chip comprising an edge coupler that is defined at least in part in the optical layer and configured to be used for coupling light into or out of the photonic chip when the photonic chip is separated from the wafer; and,
one or more test structures defined at least in part in the optical layer, each comprising one or more edge coupler pairs (ECPs), each of the one or more ECPs comprising two test edge couplers optically coupled across a test gap, wherein the test gap separates the two test edge couplers by a distance that is at most half of an edge-to-edge spacing between adjacent photonic chips;
wherein the test gap widens away from an optical axis of the edge coupler pair so as to at least partially collimate or focus light propagating between the two test edge couplers thereof.

13. The photonic wafer of claim 1 wherein the edge couplers of the photonic chips are configured for butt coupling to an optical waveguide after the photonics chips are separated from the photonic wafer, and wherein the width of the test gap is substantially equal to a nominal distance between the photonic chip and the optical waveguide in the butt coupling.

14-18. (canceled)

19. The photonic wafer of claim 1, wherein the first test structure is disposed in a test area separate from the photonics chips.

20. The photonic wafer of claim 1 wherein the first test structure is optically decoupled from the photonic chips.
